(19) United States
(12) Patent Application Publication
(10) Pub. No.: US 2024/0063599 A1
(43) Pub. Date: Feb. 22, 2024

(54) OPTICAL FIBER STRUCTURES AND METHODS FOR MULTI-WAVELENGTH POWER DELIVERY

(71) Applicant: Panasonic Intellectual Property Management Co., Ltd., Osaka (JP)

(72) Inventors: Wang-Long ZHOU, Revere, MA (US); Francisco VILLARREAL-SAUCEDO, Middleton, MA (US); Bien CHANN, Merrimack, NH (US)

(21) Appl. No.: 18/230,295

(22) Filed: Aug. 4, 2023

Related U.S. Application Data
(60) Provisional application No. 63/399,258, filed on Aug. 19, 2022.

(51) Int. Cl. H01S 3/067

(52) U.S. Cl. CPC H01S 3/06733

(57) ABSTRACT

In various embodiments, laser systems and processing techniques utilize multiple laser beams having different wavelengths coupled into optical fibers in which one region thereof is composed of doped or undoped low-OH fused silica, and another region thereof is composed of doped or undoped high-OH fused silica.

### RELATED APPLICATIONS

This application claims the benefit of and priority to U.S. Provisional Patent Application No. 63/399,258, filed Aug. 19, 2022, the entire disclosure of which is hereby incorporated herein by reference.

### TECHNICAL FIELD

In various embodiments, the present invention relates to laser systems and optical fibers, specifically laser systems and optical fibers enabling power delivery of radiation at multiple wavelengths with low absorption.

### BACKGROUND

High-power laser systems are utilized for a host of different applications, such as welding, cutting, drilling, and materials processing. Such laser systems typically include a laser emitter, the laser light from which is coupled into an optical fiber (or simply a “fiber”), and an optical system that focuses the laser light from the fiber onto the workpiece to be processed. The optical system is typically engineered to produce the highest-quality laser beam, or, equivalently, the beam with the lowest beam parameter product (BPP). The BPP is the product of the laser beam's divergence angle (half-angle) and the radius of the beam at its narrowest point (i.e., the beam waist, the minimum spot size). That is, BPP=NA×D/2, where D is the focusing spot (the waist) diameter and NA is the numerical aperture; thus, the BPP may be varied by varying NA and/or D. The BPP quantifies the quality of the laser beam and how well it can be focused to a small spot, and is typically expressed in units of millimeter-milliradians (mm-mrad). A Gaussian beam has the lowest possible BPP, given by the wavelength of the laser light divided by pi. The ratio of the BPP of an actual beam to that of an ideal Gaussian beam at the same wavelength is denoted M², which is a wavelength-independent measure of beam quality.

Optical fibers for industrial laser high-power delivery are typically composed of fused silica, mainly because fused silica exhibits lower absorption than most other optical glasses. One of the major parameters categorizing fused silica material is its content of hydroxyl ions or groups, i.e., its OH-content. For example, IR-grade fused silica typically has an OH-content less than 10 ppm (parts per million), while UV-grade fused silica may have an OH-content well over 400 ppm. Low-OH fused silica has lower absorption at near-IR (NIR) wavelengths than high-OH fused silica, and therefore it is better suited for use with NIR lasers. In contrast, UV-grade fused silica has lower absorption at UV and visible wavelengths when compared to IR-grade (i.e., low-OH) fused silica.

In addition, due to advances in the development of high-power blue and green lasers in recent years, hybrid laser systems are emerging as a new frontier in the field. These systems typically include two high-power lasers, for example, one at NIR and another at visible or UV wavelength. However, due to the aforementioned differences in absorption for fused silica optical fibers, hybrid laser systems featuring two lasers at two different wavelengths typically require the use of two different fibers, one composed of low-OH fused silica and the other composed of high-OH fused silica. Thus, there is a need for single-fiber laser systems compatible with the use of two or more lasers each emitting at a different wavelength and that exhibit low optical absorption at all such wavelengths.

### SUMMARY

Various embodiments of the present invention provide laser systems, coupling and delivery techniques, and optical fibers that enable the delivery of high-power optical radiation at different wavelengths with low absorption, utilizing a single optical delivery fiber. In various embodiments, the optical fiber has different core and cladding regions, at least one of which includes, consists essentially of, or consists of low-OH fused silica, and at least one other of which includes, consists essentially of, or consists of high-OH fused silica. In this manner, a single optical fiber may be utilized to propagate both a longer wavelength (e.g., NIR or IR) laser beam and a shorter wavelength (e.g., visible such as blue and/or UV) laser beam, in different regions of the fiber, without deleterious absorption of the different beams. In accordance with embodiments of the invention, the high-OH fused silica and/or the low-OH fused silica may be pure or substantially pure fused silica, or it may be fused silica doped with one or more dopants (e.g., Ge, F, etc.) to adjust the refractive index. That is, in accordance with the present disclosure, hydroxyl ions are not considered to be “dopants,” and undoped fused silica may be either low-OH or high-OH. One or more, or even all, regions or layers of optical fibers in accordance with embodiments of the present invention may include, consist essentially of, or consist of low-OH or high-OH fused silica, or may consist of low-OH or high-OH fused silica with unintentional impurities.

In various embodiments, the optical fiber may include one or more outer layers disposed outside of the outermost cladding layer. Such layers, or the outermost cladding later itself, may be provided for various purposes, including but not limited to BPP manipulation, fiber structural support, fiber protection, etc. Thus, such layers may include, consist essentially of, or consist of glass (e.g., fused silica, doped fused silica), a polymer, plastic, etc. Various embodiments of the invention do not incorporate mode strippers in or on the optical fiber structure. Similarly, the various layers of optical fibers in accordance with embodiments of the invention are continuous along the entire length of the fiber and do not contain holes, photonic-crystal structures, breaks, gaps, or other discontinuities therein.

Optical fibers in accordance with embodiments of the invention (which herein may also be termed “dual-fused-silica” fibers or “dual-FS” fibers) may be multi-mode fibers and therefore support multiple modes therein (e.g., more than three, more than ten, more than 20, more than 50, or more than 100 modes). In addition, fibers in accordance with the invention are generally passive fibers, i.e., are not doped with active dopants (e.g., erbium, ytterbium, thulium, neodymium, dysprosium, praseodymium, holmium, or other rare-earth metals) as are typically utilized for pumped fiber lasers and amplifiers. Rather, dopants utilized to select desired refractive indices in various layers of fibers in accordance with the present invention are generally passive dopants that are not excited by laser light, e.g., fluorine, titanium, germanium, and/or boron. Obtaining a desired refractive index for a particular layer or region of an optical fiber in accordance with embodiments of the invention may be accomplished (by techniques such as doping) by one of skill in the art without undue experimentation. Relatedly, optical fibers in accordance with embodiments of the invention may not incorporate reflectors or partial reflectors (e.g., grating such as Bragg gratings) therein or thereon. Fibers in accordance with embodiments of the invention are typically not pumped with pump light configured to generate laser light of a different wavelength. Rather, fibers in accordance with embodiments of the invention merely propagate light along their lengths without changing its wavelength.

In addition, optical fibers and systems in accordance with embodiments of the present invention are typically utilized for materials processing (e.g., cutting, drilling, etc.), rather than for applications such as optical communication or optical data transmission. Thus, laser beams coupled into fibers in accordance with embodiments of the invention typically have wavelengths less than the 1.3 μm or 1.5 μm utilized for optical communication. In fact, fibers utilized in accordance with embodiments of the present invention may exhibit dispersion at one or more (or even all) wavelengths in the range of approximately 1260 nm to approximately 1675 nm utilized for optical communication. For example, laser wavelengths utilized in accordance with embodiments of the invention may have wavelengths ranging from approximately 780 nm to approximately 1064 nm, from approximately 780 nm to approximately 1000 nm, from approximately 870 nm to approximately 1064 nm, or from approximately 870 nm to approximately 1000 nm. In various embodiments, the wavelength (or primary or center wavelength) of the laser beam may be, for example, approximately 1064 nm, approximately 970 nm, approximately 780 or 850 to approximately 1060 nm, or approximately 950 nm to approximately 1070 nm. In various embodiments, the laser wavelengths may be less than approximately 2.6 μm, as longer wavelengths may not be transmittable by fused silica optical fibers without significant losses.

In various embodiments, the shorter-wavelength laser beam has a wavelength (or range of wavelengths) in the high-energy visible (e.g., blue, green, or violet) or ultraviolet (UV) range. For example, the wavelength may range from approximately 300 nm to approximately 740 nm, approximately 400 nm to approximately 740 nm, approximately 530 nm to approximately 740 nm, approximately 300 nm to approximately 810 nm, approximately 400 nm to approximately 810 nm, or approximately 530 nm to approximately 810 nm. In various embodiments, the wavelength of the shorter-wavelength laser beam is in the UV or visible range, although the wavelength may extend up to approximately 810 nm for various applications. In particular embodiments, the wavelength (or primary or center wavelength) of the shorter-wavelength laser beam may be, for example, approximately 810 nm, approximately 400—approximately 460 nm, or approximately 532 nm. (Herein, it is understood that references to different “wavelengths” encompass different “ranges of wavelengths” or different “primary wavelengths.”)

In accordance with various embodiments of the invention, two or more laser beams, each having a different wavelength, are coupled into the optical fiber, serially and/or simultaneously, to harness advantages of each wavelength for the optimization of materials processing. Such embodiments may incorporate details and techniques described in U.S. patent application Ser. No. 16/984,489, filed on Aug. 4, 2020, the entire disclosure of which is incorporated by reference herein. For example, in various embodiments, a laser system features a primary laser emitting at a relatively longer wavelength (e.g., infrared or near-infrared) utilized for cutting materials (e.g., metallic materials), as well as a secondary laser emitting at a relatively shorter wavelength (e.g., ultraviolet or visible) utilized at least for initial piercing operations at the initiation of cutting. In general, various metals exhibit greater absorption of laser light at shorter wavelengths, at least in the solid state. Thus, shorter-wavelength lasers may be efficiently utilized for piercing operations performed at, for example, the initiation of laser cutting. That is, piercing operations may be performed more quickly, and with higher quality (e.g., edge roughness) with shorter-wavelength lasers. Unfortunately, many short-wavelength lasers (e.g., lasers emitting in the green or blue wavelength range) are less efficient, have shorter lifetimes, are more expensive, and ramp to full power more slowly and/or less easily than various longer-wavelength lasers, such as near-infrared lasers. In addition, once metals are molten, their absorbance of laser light becomes less dependent on, or even independent of, the laser wavelength. Thus, actual cutting operations, once metals are pierced and molten, may be more quickly and efficiently performed by longer-wavelength lasers, which generally have longer lifetimes and exhibit higher efficiency. Such longer-wavelength lasers may be unsuitable for the initial piercing operation, due to (1) lower absorption of the longer wavelengths by the material and/or (2) high reflectivity of the longer wavelengths by the material, which can not only prevent initiation of laser cutting but also lead to damage of the laser system (or various components thereof) by spurious reflections.

In an example cutting operation, a laser is emitted toward the surface of the material, whereupon at least a portion of the laser energy is absorbed, thereby heating the material. After sufficient energy absorption, the surface of the material melts and becomes molten. Thereafter, the sub-surface material also melts, generating a hole in the material. Once such a hole is formed, laser energy may be translated across the material, cutting through the material in a desired pattern. In accordance with various embodiments of the invention, a secondary, smaller-wavelength laser is utilized to initiate a cutting operation. In various embodiments, the secondary laser emits light onto the surface of the material to be processed at least until a portion of the surface of the material is molten. (That is, the secondary laser need not be utilized until the hole is actually generated through the material, so long as at least some of the material is molten and therefore more absorptive to laser light of longer wavelengths; however, in various embodiments, the secondary laser is utilized at least until a hole forms through the material.) After at least a portion of the material surface is molten, the primary laser emits longer-wavelength light onto the material at substantially the same point (i.e., the primary and secondary laser beams may be coaxial, since they are coupled into the same step-core optical fiber) and then translated across the material to produce a cut. Thus, in various embodiments, the secondary laser may be utilized at a lower power and/or for less time, extending its lifetime. Moreover, the use of the secondary laser enables the efficient processing of materials that are highly reflective to longer laser wavelengths (e.g., infrared or near-infrared), such as copper.

In various embodiments, the secondary laser may be utilized (i.e., may emit laser energy toward the material) not only for piercing of the material (e.g., when initiating a cutting operation), but also during the cutting operation if one or more properties of the material change or if it is desired to alter one or more properties of the cut itself. For example, if the thickness of the material changes (e.g., increases) at one or more points, the secondary laser may be utilized at such points to efficiently continue the cutting operation. In addition, the secondary laser may be utilized (with or without the primary laser) at a point where it is desired to alter (e.g., increase) the size of the cut, and/or at a point where the cutting direction changes.

As detailed above, the primary and secondary lasers may be utilized independently of each other during different portions of the piercing/cutting operation (or other processing operation). That is, the secondary laser may be utilized to initiate the cut and then turned off, whereupon the primary laser may be powered on to complete the operation, and the two lasers do not emit light toward the material simultaneously. However, in various embodiments, both lasers are coupled into the optical fiber, and therefore emit light toward the material, simultaneously for at least a portion of the processing operation. That is, the optical fiber may emit light from both lasers toward the surface during at least a portion of the piercing operation and/or during at least a portion of the subsequent cutting operation. The simultaneous use of both lasers may provide extra laser power, thereby enabling faster cutting and/or the cutting of thicker materials. In addition, the extended bandwidth provided by simultaneous use of both lasers may improve the surface quality of the processed/cut material via increases scrambling of laser coherence and speckle. In various embodiments, both lasers emit light toward the material simultaneously, but the power of one or the other is modulated during one or more portions of the process. For example, during piercing the primary laser may emit light but at a lower power than during the subsequent cutting operation. Similarly, the secondary laser may emit light during cutting, but at a lower power than during the initial piercing operation.

In various embodiments, the operation of the primary and secondary lasers, and therefore the in-coupling of the lasers into the optical fiber, is controlled by a computer-based controller. In embodiments in which the primary laser is used (or primarily used) for cutting after the secondary laser is used (or primarily used) for piercing, the controller may power on the primary laser (or ramp up its power level) at a desired point in the process (e.g., when at least a portion of the material surface is molten but before a hole is formed in the material, or even after the hole forms in the material). At such time, the controller may power off the secondary laser (or ramp down its power level). The controller may initiate this use of the primary laser directly in response to the state of the material surface (e.g., when it becomes molten). For example, the laser system may include one or more sensors that monitor the material surface and detect when it is molten via changes in, for example, reflectivity and/or temperature of the surface. (As known to those of skill in the art, when a surface becomes molten, this phase change may be accompanied by an abrupt change in reflectivity (e.g., to longer wavelengths such as infrared or near-infrared wavelengths). The temperature rise of the surface of the material may also slow, at least until the material begins to vaporize.) In other embodiments, the controller may simply initiate the use of the primary laser (and/or power down or off the secondary laser) after a timed delay.

Thus, in various embodiments, a secondary, shorter wavelength laser is utilized (or primarily utilized) to melt, pierce, or partially pierce a material and, thereafter, a primary, longer wavelength laser is utilized (or primarily utilized) to cut the material (e.g., via translation of the primary laser spot across the material). In general, the secondary laser may be utilized to initiate a particular process, while the primary laser may be utilized to complete the process after it is initiated. While such embodiments may be particularly suited to metallic materials, in various embodiments the longer wavelength laser is utilized (or primarily utilized) to melt, pierce, or partially pierce a material and, thereafter, the shorter wavelength laser is utilized (or primarily utilized) to cut the material (e.g., via translation of the primary laser spot across the material). For example, many non-metallic materials such as glasses and plastics are transparent at visible and near-IR wavelengths, but may exhibit high absorption at UV wavelengths (e.g., less than approximately 350 nm) and/or IR wavelengths (e.g., ranging from approximately 2 μm to approximately 11 μm). Thus, while such materials may be processed as detailed above and herein, i.e., with the shorter wavelength laser for piercing and/or melting, and the longer wavelength laser for cutting, the laser wavelengths may be selected so that such materials may be processed with the longer wavelength laser used for piercing and/or melting, and the shorter wavelength laser used for cutting. Thus, for such materials, the “secondary laser” as described herein may have a longer wavelength than the “primary laser” in various embodiments.

Herein, “optical elements” may refer to any of lenses, mirrors, prisms, gratings, and the like, which redirect, reflect, bend, or in any other manner optically manipulate electromagnetic radiation, unless otherwise indicated. Herein, beam emitters, emitters, or laser emitters, or lasers include any electromagnetic beam-generating device such as semiconductor elements, which generate an electromagnetic beam, but may or may not be self-resonating. These also include fiber lasers, disk lasers, non-solid state lasers, etc. An emitter may include or consist essentially of multiple beam emitters such as a diode bar configured to emit multiple beams. The input beams received in the embodiments herein may be single-wavelength or multi-wavelength beams combined using various techniques known in the art. The output beams produced in embodiments of the invention may be single-wavelength or multi-wavelength beams.

Embodiments of the invention may be utilized with wavelength beam combining (WBC) systems that include a plurality of emitters, such as one or more diode bars, that are combined using a dispersive element to form a multi-wavelength beam. Each emitter in the WBC system individually resonates, and is stabilized through wavelength-specific feedback from a common partially reflecting output coupler that is filtered by the dispersive element along a beam-combining dimension. Exemplary WBC systems are detailed in U.S. Pat. No. 6,192,062, filed on Feb. 4, 2000, U.S. Pat. No. 6,208,679, filed on Sep. 8, 1998, U.S. Pat. No. 8,670,180, filed on Aug. 25, 2011, and U.S. Pat. No. 8,559,107, filed on Mar. 7, 2011, the entire disclosure of each of which is incorporated by reference herein. Multi-wavelength output beams of WBC systems may be utilized as input beams in conjunction with embodiments of the present invention for, e.g., BPP control. Thus, in various embodiments, a laser beam source includes, consists essentially of, or consists of a WBC laser emitting a broadband, multi-wavelength laser beam. In various embodiments, such lasers may have bandwidths ranging from, for example, approximately 10 nm to approximately 60 nm. The laser beam source may be a direct-diode laser source, as opposed to a fiber or chemical laser.

Output beams produced in accordance with embodiments of the present invention may be utilized to process a workpiece such that the surface of the workpiece is physically altered and/or such that a feature is formed on or within the surface, in contrast with optical techniques that merely probe a surface with light (e.g., reflectivity measurements) and with optical beams utilized for data transmission. Exemplary processes in accordance with embodiments of the invention include cutting, welding, drilling, and soldering. As such, optical fibers detailed herein may have at their output ends a laser head configured to focus the output beam from the fiber toward a workpiece to be processed. The laser head may include, consist essentially of, or consist of one or more optical elements for focusing and/or collimating the output beam, and/or controlling the polarization and/or the trajectory of the beam. The laser head may be positioned to emit the output beam toward a workpiece and/or toward a platform or positionable gantry on which the workpiece may be disposed.

Various embodiments of the invention may also process workpieces at one or more spots or along a one-dimensional linear or curvilinear processing path, rather than flooding all or substantially all of the workpiece surface with radiation from the laser beam. In general, processing paths may be curvilinear or linear, and “linear” processing paths may feature one or more directional changes, i.e., linear processing paths may be composed of two or more substantially straight segments that are not necessarily parallel to each other. Similarly, “curvilinear” paths may be composed of multiple curvilinear segments with directional changes therebetween. Other processing paths in accordance with embodiments of the invention include segmented paths in which each segment is linear or curvilinear, and a directional change may be present between any two of the segments.

Embodiments of the invention may vary beam shape and/or BPP to improve or optimize performance for different types of processing techniques or different types of materials being processed. Embodiments of the invention may utilize various additional techniques for varying BPP and/or shape of laser beams described in U.S. patent application Ser. No. 14/632,283, filed on Feb. 26, 2015, U.S. patent application Ser. No. 14/747,073, filed Jun. 23, 2015, U.S. patent application Ser. No. 14/852,939, filed Sep. 14, 2015, U.S. patent application Ser. No. 15/188,076, filed Jun. 21, 2016, U.S. patent application Ser. No. 15/479,745, filed Apr. 5, 2017, and U.S. patent application Ser. No. 15/649,841, filed Jul. 14, 2017, the disclosure of each of which is incorporated in its entirety herein by reference.

In an aspect, embodiments of the invention feature a laser system for processing a workpiece. The laser system includes, consists essentially of, or consists of an optical fiber having an input end and an output end opposite the input end, a primary laser emitter configured to emit a primary laser beam, a secondary laser emitter configured to emit a secondary laser beam, and a coupling mechanism for coupling the primary laser beam and the secondary laser beam into the input end of the optical fiber. A wavelength of the primary laser beam is longer than a wavelength of the secondary laser beam. The optical fiber includes, consists essentially of, or consists of (i) a center core having a refractive index n0, (ii) surrounding the center core, a first cladding layer having a refractive index n1, (iii) surrounding the first cladding layer, a ring core having a refractive index n2, and (iv) surrounding the ring core, a second cladding layer having a refractive index n3. n3 is less than n0 and n3 is less than n2. Either (i) the center core is composed of, includes, consists essentially of, or consists of doped or undoped low-OH fused silica having an OH content of 10 ppm or less, and the ring core is composed of, includes, consists essentially of, or consists of doped or undoped high-OH fused silica having an OH content of 200 ppm or more, or (ii) the center core is composed of, includes, consists essentially of, or consists of doped or undoped high-OH fused silica having an OH content of 200 ppm or more, and the ring core is composed of, includes, consists essentially of, or consists of doped or undoped low-OH fused silica having an OH content of 10 ppm or less.

Embodiments of the invention may include one or more of the following in any of a variety of combinations. The coupling mechanism may include, consist essentially of, or consist of one or more of a focusing lens, a prism, and a dichroic mirror. The primary laser beam may include, consist essentially of, or consist of infrared and/or near-infrared light, and the secondary laser beam may include, consist essentially of, or consist of visible and/or ultraviolet light. The primary laser beam may include, consist essentially of, or consist of light having a wavelength ranging from approximately 800 nm to approximately 1100 nm. The secondary laser beam may include, consist essentially of, or consist of light having a wavelength ranging from approximately 400 nm to approximately 550 nm.

The center core may include, consist essentially of, consist of, or be composed of doped or undoped high-OH fused silica, and the ring core may include, consist essentially of, consist of, or be composed of doped or undoped low-OH fused silica. The coupling mechanism may be configured to couple the primary laser beam into the ring core and couple the secondary laser beam into the center core. n0 may be approximately equal to n2, and n1 may be approximately equal to n3. A thickness of the first cladding layer may be less than approximately 15 μm, less than approximately 10 μm, or less than approximately 5 μm. n0 may be approximately equal to n2. n1 may be greater than n3. sqrt(n1²−n3²) may be greater than 0.15. sqrt(n0²−n1²) may be greater than 0.1. The first cladding layer may include, consist essentially of, consist of, or be composed of doped or undoped low-OH fused silica. The coupling mechanism may be configured to also couple the primary laser beam into the first cladding layer, and/or to also couple the secondary laser beam into the first cladding layer.

n0 may be less than n2. n1 may be greater than n3. sqrt(n1²−n3²) may be greater than 0.15. sqrt(n0²−n1²) may be greater than 0.1. sqrt(n2²−n1²) may be greater than 0.13. The first cladding layer may include, consist essentially of, consist of, or be composed of doped or undoped high-OH fused silica. The coupling mechanism may be configured to also couple the secondary laser beam into the first cladding layer.

The center core may include, consist essentially of, consist of, or be composed of doped or undoped low-OH fused silica, and the ring core may include, consist essentially of, consist of, or be composed of doped or undoped high-OH fused silica. The coupling mechanism may be configured to couple the primary laser beam into the ring core and couple the secondary laser beam into the center core. n0 may be approximately equal to n2, and n1 may be approximately equal to n3. A thickness of the first cladding layer may be less than approximately 15 μm, less than approximately 10 μm, or less than approximately 5 μm.

The output end of the optical fiber may be coupled to a laser head containing one or more optical elements therein. The primary laser emitter may include, consist essentially of, or consist of (i) one or more beam sources emitting a plurality of discrete beams, (ii) focusing optics for focusing the plurality of beams toward a dispersive element, (iii) the dispersive element for receiving and dispersing the received focused beams, and (iv) a partially reflective output coupler positioned to receive the dispersed beams, transmit a portion of the dispersed beams therethrough as the primary laser beam, and reflect a second portion of the dispersed beams back toward the dispersive element (and, e.g., thence to the one or more beam emitters to stabilize the emission wavelengths thereof). The primary laser beam may be composed of multiple wavelengths. The dispersive element may include, consist essentially of, or consist of a diffraction grating (e.g., a transmissive diffraction grating or a reflective diffraction grating). The secondary laser emitter may include, consist essentially of, or consist of (i) one or more beam sources emitting a plurality of discrete beams, (ii) focusing optics for focusing the plurality of beams toward a dispersive element, (iii) the dispersive element for receiving and dispersing the received focused beams, and (iv) a partially reflective output coupler positioned to receive the dispersed beams, transmit a portion of the dispersed beams therethrough as the secondary laser beam, and reflect a second portion of the dispersed beams back toward the dispersive element (and, e.g., thence to the one or more beam emitters to stabilize the emission wavelengths thereof). The secondary laser beam may be composed of multiple wavelengths. The dispersive element may include, consist essentially of, or consist of a diffraction grating (e.g., a transmissive diffraction grating or a reflective diffraction grating).

In another aspect, embodiments of the invention feature a laser system for processing a workpiece. The laser system includes, consists essentially of, or consists of an optical fiber having an input end and an output end opposite the input end, a primary laser emitter configured to emit a primary laser beam, a secondary laser emitter configured to emit a secondary laser beam, and a coupling mechanism for coupling the primary laser beam and the secondary laser beam into the input end of the optical fiber. A wavelength of the primary laser beam is longer than a wavelength of the secondary laser beam. The optical fiber includes, consists essentially of, or consists of (i) a center core having a refractive index n0, (ii) surrounding the center core, a first cladding layer having a refractive index n1, and (iii) surrounding the first cladding layer, a second cladding layer having a refractive index n2. n2 is less than n1 and n2 is less than n0. Either (i) the center core is composed of, includes, consists essentially of, or consists of doped or undoped low-OH fused silica having an OH content of 10 ppm or less, and the first cladding layer is composed of, includes, consists essentially of, or consists of doped or undoped high-OH fused silica having an OH content of 200 ppm or more, or (ii) the center core is composed of, includes, consists essentially of, or consists of doped or undoped high-OH fused silica having an OH content of 200 ppm or more, and the first cladding layer is composed of, includes, consists essentially of, or consists of doped or undoped low-OH fused silica having an OH content of 10 ppm or less.

Embodiments of the invention may include one or more of the following in any of a variety of combinations. The coupling mechanism may include, consist essentially of, or consist of one or more of a focusing lens, a prism, and a dichroic mirror. The primary laser beam may include, consist essentially of, or consist of infrared and/or near-infrared light, and the secondary laser beam may include, consist essentially of, or consist of visible and/or ultraviolet light. sqrt(n1²−n2²) may be greater than 0.15. sqrt(n0²−n1²) may be greater than 0.1. The primary laser beam may include, consist essentially of, or consist of light having a wavelength ranging from approximately 800 nm to approximately 1100 nm. The secondary laser beam may include, consist essentially of, or consist of light having a wavelength ranging from approximately 400 nm to approximately 550 nm.

The coupling mechanism may be configured to couple the primary laser beam and the secondary laser beam into the input end of the optical fiber by directing the primary laser beam and secondary laser beam to the input end of the optical fiber in parallel to each other. The coupling mechanism may be configured to couple the primary laser beam and the secondary laser beam into the input end of the optical fiber such that a focal spot of the primary laser beam at the input end of the optical fiber is smaller than a focal spot of the secondary laser beam at the input end of the optical fiber.

The center core may include, consist essentially of, consist of, or be composed of doped or undoped low-OH fused silica, and the first cladding layer may include, consist essentially of, consist of, or be composed of doped or undoped high-OH fused silica. The coupling mechanism may be configured to couple the primary laser beam into the center core and to couple the secondary laser beam into the center core and the first cladding layer.

The center core may include, consist essentially of, consist of, or be composed of doped or undoped high-OH fused silica, and the first cladding layer may include, consist essentially of, consist of, or be composed of doped or undoped low-OH fused silica. The coupling mechanism may be configured to couple the primary laser beam into the center core and the first cladding layer and to couple the secondary laser beam into the center core.

The output end of the optical fiber may be coupled to a laser head containing one or more optical elements therein. The primary laser emitter may include, consist essentially of, or consist of (i) one or more beam sources emitting a plurality of discrete beams, (ii) focusing optics for focusing the plurality of beams toward a dispersive element, (iii) the dispersive element for receiving and dispersing the received focused beams, and (iv) a partially reflective output coupler positioned to receive the dispersed beams, transmit a portion of the dispersed beams therethrough as the primary laser beam, and reflect a second portion of the dispersed beams back toward the dispersive element (and, e.g., thence to the one or more beam emitters to stabilize the emission wavelengths thereof). The primary laser beam may be composed of multiple wavelengths. The dispersive element may include, consist essentially of, or consist of a diffraction grating (e.g., a transmissive diffraction grating or a reflective diffraction grating). The secondary laser emitter may include, consist essentially of, or consist of (i) one or more beam sources emitting a plurality of discrete beams, (ii) focusing optics for focusing the plurality of beams toward a dispersive element, (iii) the dispersive element for receiving and dispersing the received focused beams, and (iv) a partially reflective output coupler positioned to receive the dispersed beams, transmit a portion of the dispersed beams therethrough as the secondary laser beam, and reflect a second portion of the dispersed beams back toward the dispersive element (and, e.g., thence to the one or more beam emitters to stabilize the emission wavelengths thereof). The secondary laser beam may be composed of multiple wavelengths. The dispersive element may include, consist essentially of, or consist of a diffraction grating (e.g., a transmissive diffraction grating or a reflective diffraction grating).

In yet another aspect, embodiments of the invention feature a method of processing a workpiece. A laser system, which may include, consist essentially of, or consist of any laser system described above or herein, is provided. A workpiece is disposed proximate the output end of the optical fiber. The primary laser emitter is caused to emit the primary laser beam, and/or the secondary laser emitter is caused to emit the secondary laser beam, whereby an output beam is emitted from the output end of the optical fiber. The workpiece is processed with the output beam.

Embodiments of the invention may include one or more of the following in any of a variety of combinations. The workpiece may be processed along a linear or curvilinear processing path extending across at least a portion of the workpiece. Processing the workpiece may include, consist essentially of, or consist of physically altering at least a portion of a surface of the workpiece. Processing the workpiece may include, consist essentially of, or consist of cutting, welding, etching, annealing, drilling, soldering, and/or brazing. The workpiece may be processed in multiple stages. In at least one of the stages, only the primary laser beam may be emitted to form the output beam, and in at least another one of the stages, only the secondary laser beam may be emitted to form the output beam. In at least one of the stages, both the primary laser beam and the secondary laser beam may be emitted to form the output beam.

In another aspect, embodiments of the invention feature an optical fiber that includes, consists essentially of, or consists of a center core, a first cladding layer, a ring core, and a second cladding layer. The center core (i) has a refractive index n0 and (ii) includes, consists essentially of, consists of, or is composed of doped or undoped high-OH fused silica having an OH content of 200 ppm or more. The first cladding layer surrounds the center core and has a refractive index n1. The ring core surrounds the first cladding layer and (i) has a refractive index n2 and (ii) includes, consists essentially of, consists of, or is composed of doped or undoped low-OH fused silica having an OH content of 10 ppm or less. The second cladding layer surrounds the ring core and has a refractive index n3. n3 is less than n0 and n3 is less than n2.

Embodiments of the invention may include one or more of the following in any of a variety of combinations. n0 may be approximately equal to n2. n1 may be approximately equal to n3. A thickness of the first cladding layer may be less than approximately 15 μm, less than approximately 10 μm, or less than approximately 5 μm.

n0 may be approximately equal to n2. n1 may be greater than n3. sqrt(n1²−n3²) may be greater than 0.15. sqrt(n0²−n1²) may be greater than 0.1. The first cladding layer may include, consist essentially of, consist of, or be composed of doped or undoped low-OH fused silica.

n0 may be less than n2. n1 may be greater than n3. sqrt(n1²−n3²) may be greater than 0.15. sqrt(n0²−n1²) may be greater than 0.1. sqrt(n2²−n1²) may be greater than 0.13. The first cladding layer may include, consist essentially of, consist of, or be composed of doped or undoped high-OH fused silica.

The optical fiber may have an input end optically coupled to (i) a primary laser emitter configured to emit a primary laser beam and (ii) a secondary laser emitter configured to emit a secondary laser beam. A wavelength of the primary laser beam may be longer than a wavelength of the secondary laser beam. The optical fiber may have an output end coupled to a laser head containing one or more optical elements therein. In yet another aspect, embodiments of the invention feature an optical fiber that includes, consists essentially of, or consists of a center core, a first cladding layer, a ring core, and a second cladding layer. The center core (i) has a refractive index n0 and (ii) includes, consists essentially of, consists of, or is composed of doped or undoped low-OH fused silica having an OH content of 10 ppm or less. The first cladding layer surrounds the center core and has a refractive index n1. The ring core surrounds the first cladding layer and (i) has a refractive index n2 and (ii) includes, consists essentially of, consists of, or is composed of doped or undoped high-OH fused silica having an OH content of 200 ppm or more. The second cladding layer surrounds the ring core and has a refractive index n3. n3 is less than n0 and n3 is less than n2.

Embodiments of the invention may include one or more of the following in any of a variety of combinations. n0 may be approximately equal to n2. n1 may be approximately equal to n3. A thickness of the first cladding layer may be less than approximately 15 μm, less than approximately 10 μm, or less than approximately 5 μm. The optical fiber may have an input end optically coupled to (i) a primary laser emitter configured to emit a primary laser beam and (ii) a secondary laser emitter configured to emit a secondary laser beam. A wavelength of the primary laser beam may be longer than a wavelength of the secondary laser beam. The optical fiber may have an output end coupled to a laser head containing one or more optical elements therein.

In another aspect, embodiments of the invention feature an optical fiber that includes, consists essentially of, or consists of a center core, a first cladding layer, and a second cladding layer. The center core (i) has a refractive index n0 and (ii) includes, consists essentially of, consists of, or is composed of doped or undoped low-OH fused silica having an OH content of 10 ppm or less. The first cladding layer surrounds the center core and (i) has a refractive index n1 and (ii) includes, consists essentially of, consists of, or is composed of doped or undoped high-OH fused silica having an OH content of 200 ppm or more. The second cladding layer surrounds the first cladding layer and has a refractive index n2. n2 is less than n1 and n2 is less than n0.

Embodiments of the invention may include one or more of the following in any of a variety of combinations. sqrt(n1²−n2²) may be greater than 0.15. sqrt(n0²−n1²) may be greater than 0.1. The optical fiber may have an input end optically coupled to (i) a primary laser emitter configured to emit a primary laser beam and (ii) a secondary laser emitter configured to emit a secondary laser beam. A wavelength of the primary laser beam may be longer than a wavelength of the secondary laser beam. The optical fiber may have an output end coupled to a laser head containing one or more optical elements therein.

In yet another aspect, embodiments of the invention feature an optical fiber that includes, consists essentially of, or consists of a center core, a first cladding layer, and a second cladding layer. The center core (i) has a refractive index n0 and (ii) includes, consists essentially of, consists of, or is composed of doped or undoped high-OH fused silica having an OH content of 200 ppm or more. The first cladding layer surrounds the center core and (i) has a refractive index n1 and (ii) includes, consists essentially of, consists of, or is composed of doped or undoped low-OH fused silica having an OH content of 10 ppm or less. The second cladding layer surrounds the first cladding layer and has a refractive index n2. n2 is less than n1 and n2 is less than n0.

Embodiments of the invention may include one or more of the following in any of a variety of combinations. sqrt(n1²−n2²) may be greater than 0.15. sqrt(n0²−n1²) may be greater than 0.1. The optical fiber may have an input end optically coupled to (i) a primary laser emitter configured to emit a primary laser beam and (ii) a secondary laser emitter configured to emit a secondary laser beam. A wavelength of the primary laser beam may be longer than a wavelength of the secondary laser beam. The optical fiber may have an output end coupled to a laser head containing one or more optical elements therein.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein, the term “substantially” means±10%, and in some embodiments, ±5%. The term “consists essentially of” means excluding other materials that contribute to function, unless otherwise defined herein. Nonetheless, such other materials may be present, collectively or individually, in trace amounts. Herein, the terms “radiation” and “light” are utilized interchangeably unless otherwise indicated. Herein, “downstream” or “optically downstream,” is utilized to indicate the relative placement of a second element that a light beam strikes after encountering a first element, the first element being “upstream,” or “optically upstream” of the second element. Herein, “optical distance” between two components is the distance between two components that is actually traveled by light beams; the optical distance may be, but is not necessarily, equal to the physical distance between two components due to, e.g., reflections from mirrors or other changes in propagation direction experienced by the light traveling from one of the components to the other. Distances utilized herein may be considered to be “optical distances” unless otherwise specified.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A is a graph of absorption spectra for high-OH and low-OH fused silica;

FIG. 1B is a table of optical absorptions for high-OH and low-OH fused silica at various wavelengths;

FIG. 2 is a schematic diagram of example refractive indices of the various layers of an optical fiber in accordance with various embodiments of the invention;

FIG. 3 tabulates various characteristics and advantages of different embodiments, or “Formats” of optical fibers, and systems incorporated them, in accordance with various embodiments of the invention;

FIG. 4 is a schematic diagram of portions of a laser system utilizing an optical fiber in accordance with various embodiments of the invention;

FIG. 5 is a schematic diagram of example refractive indices of the various layers of an optical fiber in accordance with various embodiments of the invention;

FIG. 6 is a schematic diagram of a laser resonator in accordance with various embodiments of the invention;

FIG. 7A is a schematic view of a first side of a laser resonator in accordance with various embodiments of the invention;

FIG. 7B is a schematic view of a second side of a laser resonator in accordance with various embodiments of the invention; and

FIG. 8 is a schematic view of a laser engine in accordance with various embodiments of the invention.

### DETAILED DESCRIPTION

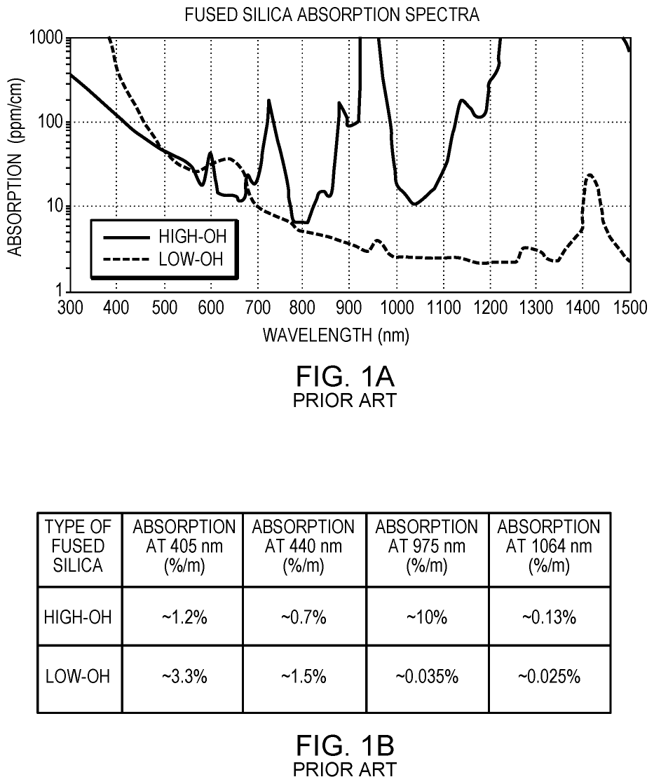

FIG. 1A depicts the absorption spectra of UV grade (high-OH) and IR grade (low-OH) fused silica in units of ppm/cm. (The original data set for FIG. 1A in units of dB/km is publicly available from Thorlabs, Inc. at Thorlabs.com.) As shown in FIG. 1A, low-OH fused silica exhibits much less absorption at most NIR wavelengths above 700 nm, while high-OH fused silica generally has lower absorption at visible and UV wavelengths, especially at wavelengths less than 500 nm. FIG. 1B lists high-OH and low-OH fused silica absorption values in units of %/m at a few example wavelengths.

In an exemplary embodiment, if one assumes that a hybrid laser system features a 10 kW NIR laser emitting at 975 nm and a 2 kW blue laser emitting at 440 nm, the potential power losses per meter at NIR and blue wavelengths in an optical fiber due to absorption would be, respectively, 3.5 W and 30 W if delivered with a low-OH fused silica fiber or 1 kW and 14 W if delivered with a high-OH fused silica fiber. Therefore, high-OH fiber is typically unacceptable for use with high-power NIR lasers, especially those having emission wavelengths around 975 nm. Moreover, in many cases, low-OH fiber may be unacceptable for use with high-power visible or UV lasers.

The difference in absorption at blue wavelengths of high-OH and low-OH fused silica may be not as significant as that at NIR wavelengths, but it may still have a large impact, particularly for some applications. For example, since the cost per watt at blue wavelengths is much higher than at NIR wavelengths, an absorption loss of −1%/m in the optical fiber severely limits the total length of the delivery fiber for the blue laser, and this has a significant impact on the flexibility and maneuverability in actual processing applications. As an example, if an application requires that the total fiber loss be no more than 5%, the maximum allowed length of the fiber will be 7 meters if made of high-OH fused silica, or only 3.3 meters if made of low-OH fused silica.

A conventional solution for this dilemma is to utilize two separate delivery fibers, a low-OH fused silica fiber designated for NIR wavelengths and a high-OH one for the visible or UV wavelengths. However, two separate delivery fibers not only substantially increases the overall cost, but it also deleteriously increases the complexity of the system.

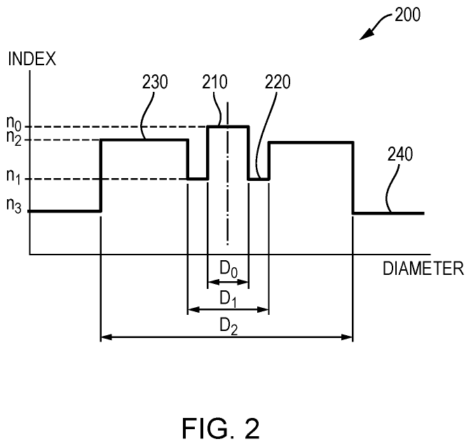

FIG. 2 depicts an exemplary fiber profile of refractive indices of an optical fiber 200 in accordance with various embodiments of the present invention, for high-power delivery in a hybrid laser system having at least two high-power lasers, one emitting at a longer wavelength (e.g., NIR at approximately 975 nm) and another at a shorter wavelength (e.g., visible or UV, for example blue at approximately 440 nm). While examples herein refer to NIR and blue or UV lasers, these particular lasers are only exemplary, and many other combinations are possible. In various embodiments, NIR light corresponds to wavelengths ranging from approximately 800 nm to approximately 1100 nm, while “visible and UV” light corresponds to wavelengths ranging from approximately 400 nm to approximately 550 nm.

It is understood that references herein to NIR and blue/UV lasers are not limiting and more generally represent lasers emitting at different wavelengths, one longer than the other (e.g., a “longer wavelength” laser and a “shorter wavelength” laser). In various embodiments, the difference in wavelength (or primary or center wavelength) between the two lasers is at least approximately 300 nm, at least approximately 400 nm, or at least approximately 500 nm, and may be at most approximately 1000 nm, at most approximately 900 nm, or at most approximately 800 nm.

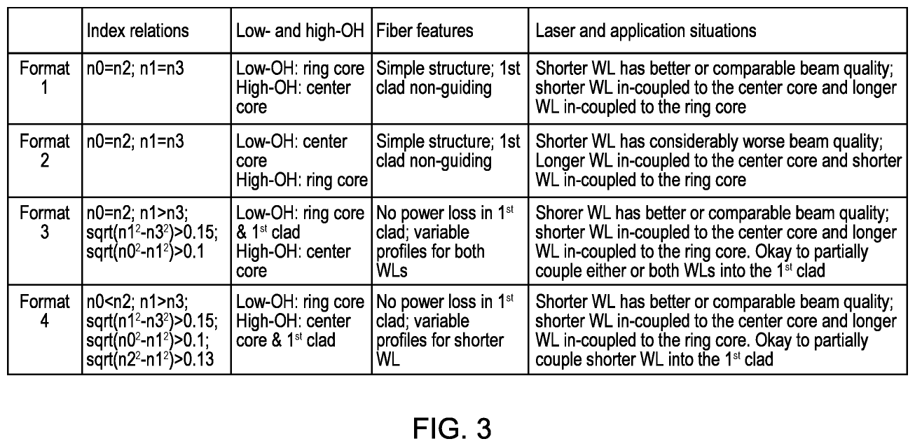

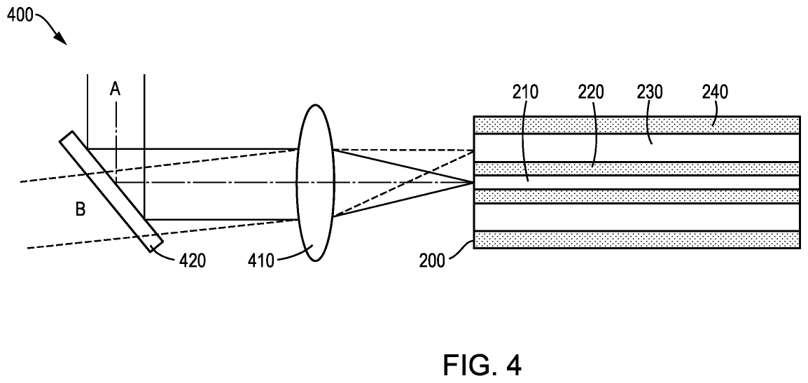

The exemplary fiber 200 of FIG. 2 has a center core 210, a first cladding 220, a second cladding 230, and a third cladding 240. In various embodiments, the center core 210 and the various claddings may each include, consist essentially of, or consist of either low-OH fused silica or high-OH fused silica; as detailed below, different configurations in accordance with embodiments of the invention have these materials in different locations in the fiber. The illustrated differences of refractive index among the core and the cladding layers may be achieved via doping (with, e.g., dopants such as fluorine and/or germanium). The second cladding 230 may function as a ring core, and therefore the depicted fiber may also be designated as a multi-clad fiber or a multi-core fiber. As shown in FIG. 2, the third cladding 240 has the lowest refractive index and is typically a non-guiding layer. In accordance with various embodiments of the invention, the diameter D₀ of the center core 210 may be approximately 150 μm or less, or even approximately 100 μm or less. In accordance with various embodiments of the invention, the diameter D₂ of the second cladding 230 may be approximately 200 μm or more. In accordance with various embodiments of the invention, the thickness of the first cladding 220 may be quite small (e.g., approximately 10 μm or less, approximately 8 μm or less, or approximately 5 μm or less) if the first cladding 230 is not intended to guide light (for example, Formats 1 and 2 of FIG. 3 described below). In other embodiments, first cladding 220 may contain and guide light (for example, Formats 3 and 4 of FIG. 4 described below), and its thickness may be greater; for example, the thickness of the first cladding 220 may be up to approximately 30 μm or even up to approximately 40 μm (e.g., ranging from approximately 15 μm or approximately 20 μm to approximately 30 μm or approximately 40 μm). While a thicker first cladding 220 may result in a thicker overall fiber diameter, it also will enable a greater range of laser profile variations, in accordance with embodiments of the invention.

As utilized herein, the concentration of hydroxyl ions in “low-OH” fused silica is at most 10 ppm, at most 5 ppm, or at most 2 ppm; the concentration of hydroxyl ions in “high-OH” fused silica is at least 200 ppm, at least 400 ppm, or at least 800 ppm.

In accordance with various embodiments of the invention, the optical fiber having both low-OH and high-OH regions may be fabricated via, for example, drawing of fused silica preform rods, a technique known to those of skill in the art. In this technique, a preform rod having the desired regions is drawn to increase its length and decrease its diameter; for example, a preform rod having a diameter of 20 mm and length of 100 mm may be drawn to produce approximately 1 km of 200 μm-diameter fiber.

In various embodiments, the fused silica preform rod may be conventionally fabricated via chemical vapor deposition, and may involve the burning of silica tetrachloride (SiCl₄) in a hydrogen-oxygen flame to form a fine powder of synthetic silica. The deposition may be applied layer by layer on the inner surface of a pure fused silica tube or on the outer surface of a glass rod. Deposition thickness and doping levels (i.e., refractive index) of each layer may be precisely controlled via this technique. The fine silica powder layers are then fused, e.g., at around 1800° C., to become clear glass, and the tube may be collapsed at, e.g., 2000° C. or above, to become a solid preform rod. Additional layers may be formed by collapsing a tube over a rod (i.e., the “rod-in-tube” method). Such tubes and rods may be preformed with desired concentrations of hydroxyl ions in order to form the final desired regions of the optical fiber.

The concentration of hydroxyl ions in each layer or region may be controlled during the deposition process by regulating the hydrogen level in the flame. For example, the OH-content may be reduced via a purging process of a drying gas after deposition. For OH contents less than 10 ppm, water-vapor-free plasma flames may be utilized. For regions of higher OH content, water vapor may be introduced during or after deposition.

Depending on the applications and the beam parameters of the two lasers of a hybrid laser system in accordance with embodiments of the invention, the optical fiber may have various different configurations in terms of refractive index profile, allocation of low-OH and high-OH fused silica, and diameter or thickness of fiber layers. FIG. 3 lists a few example configurations of optical fibers in accordance with embodiments of the invention.

As shown in FIG. 3, optical fibers of Format 1 and Format 2 are structurally similar to a conventional dual-core fiber but have both low-OH and high-OH fused silica in different regions of the same fiber. Format 1 has a high-OH center core and therefore is intended for coupling the shorter-wavelength laser into the center core. In contrast, Format 2 has low-OH center core and is designed for the longer-wavelength laser to be coupled into the center core. In Format 1 and Format 2 fibers, the first cladding 220 is a non-guiding layer, because it has the same low refractive index as the third cladding 240, i.e., n1=n3. The layer thickness of the first cladding 220 is preferably fairly small, e.g., less than approximately 15 μm, less than approximately 10 μm, or even less than approximately 5 μm, in order to reduce potential power loss in the first cladding layer 220.

Format 3 in FIG. 3 is an example variation of Format 1, in which the refractive index of the first cladding 220 is increased so that n1>n3 and sqrt(n1²−n3²)>0.15. The latter relationship defines the numerical aperture (NA) of the first cladding 220 relative to the third cladding 240. A NA of at least 0.15 implies that the power loss in the first cladding 220 will be minimized even when the laser is initially in-coupled into the first cladding 220, at least for most industrial lasers. In Format 3, the first cladding refractive index n1 is further constrained by sqrt(n0²−n1²)>0.1 so that most of the power initially coupled into the center core 210 or ring core 230 will remain in the center core 210 or ring core 230.

Similar to Format 1, Format 3 has a high-OH center core 210 and low-OH ring core 230 and is intended for shorter-wavelength (e.g., blue or UV) light coupled into the center core 210 and longer-wavelength (e.g., NIR) light coupled into the ring core 230. In order to reduce the risk of fiber burning by the longer-wavelength laser, the first cladding 220 of Format 3 preferably includes, consists essentially of, or consists of low-OH fused silica. Format 3 also provides the advantageous feature of dynamic beam shaping, i.e., variable output laser profiles. This feature may be realized by changing the in-coupling power ratio between the ring core 230 and the first cladding 220 for the longer-wavelength laser or the ratio between the center core 210 and the first cladding 220 for the shorter-wavelength laser.

Format 4 of FIG. 3 is an example variation of Format 3, in which the center core refractive index is decreased (n0<n2), and in which the first cladding refractive index n1 is restricted so that the NA of the ring core 230 relative to the first cladding 220 is sqrt(n2²−n1²)>0.13. NA>0.13 implies that the power coupled into the ring core 230 will have very little chance to escape to the first cladding 220 for most industrial lasers. In various embodiments, Format 4 is intended for applications in which the longer-wavelength laser is only coupled into the ring core 230, and the shorter-wavelength laser is coupled to the center core 210 with partial power possibly being coupled into the first cladding 220. The first cladding 220 in Format 4 preferably comprises, consists essentially of, or consists of high-OH fused silica.

FIG. 4 depicts a laser system 400 in which two lasers, A and B, one having a longer wavelength (e.g., NIR) and another having a shorter wavelength (e.g., blue or UV), are coupled via an in-coupling mechanism, such as a dichroic mirror 410 and a focusing lens 420 (or lens system) into fiber 200. The fiber 200 may be, for example, one of the variations listed in FIG. 3 and detailed above. As shown, the fiber 200 has the center core 210, the first cladding 220, the second cladding or the ring core 230, and the third cladding 240. In various embodiments, the two lasers reach the focusing lens 410 at a small angle therebetween so that laser A is coupled into the center core 210 and laser B is coupled into the ring core 230. Since the two lasers are well separated in wavelength, the small angle may also be created by inserting a prism before the focusing lens 410 if the two lasers approach the focusing lens approximately parallel to each other.

In various embodiments, an angle a between the two laser beams is determined by a=a tan(s/f), where f is the focal length of lens 410 and s is the separation of the two focal spots on the input end of fiber 200. For example, if f=30 mm and s=200 μm, then a=˜0.38°. In accordance with embodiments of the invention, the angle between the beams may be less than approximately 1°, less than approximately 0.8°, less than approximately 0.5°, or less than approximately 0.4°.

Three of the four example fiber configurations shown in FIG. 3 are intended to have the blue or shorter-wavelength laser coupled into the center core, because lasers emitting at shorter wavelength may be typically focused into a smaller spot. However, high-power NIR lasers with good beam quality (e.g., BPP<5 mm·mrad) are readily available and may be easily coupled into 100 μm or even smaller fibers, while most commercially available high-power blue lasers may have fairly bad beam quality with BPP ranging from 20˜80 mm·mrad, which would typically require fibers of diameters of approximately 200 μm to approximately 1 mm for in-coupling.

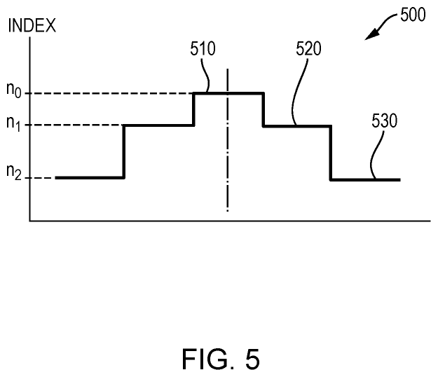

FIG. 5 illustrates a simplified design of an optical fiber 500, in accordance with various embodiments of the invention, having a center core 510 including, consisting essentially of, or consisting of low-OH for a longer-wavelength (e.g., NIR) laser and a first cladding 520 including, consisting essentially of, or consisting of high-OH for a shorter-wavelength (e.g., blue or UV) laser. In the non-limiting example of FIG. 5, the first cladding refractive index n1 is defined by sqrt(n1²−n2²)>0.15 and sqrt(n0²−n1²)>0.1. In the depicted embodiment of FIG. 5, the optical fiber 500 also has a second cladding 530 having a refractive index n2 that is less than n1. In various embodiments, the second cladding 530 includes, consists essentially of, or consists of the same type of fused silica (i.e., either low-OH or high-OH) as the first cladding 520 (e.g., high-OH when the first cladding 520 is meant for a shorter-wavelength laser, or low-OH when the first cladding 520 is meant for a longer-wavelength laser).

In accordance with various embodiments of the invention, the diameter of the center core 510 may be approximately 150 μm or less, or even approximately 100 μm or less. In accordance with various embodiments of the invention, the diameter of the first cladding 520 may be approximately 200 μm or more, or even approximately 400 μm or more. In accordance with various embodiments of the invention, the diameter of the second cladding 530 is relatively thin (e.g., ranging from approximately 10 μm to approximately 15 μm or approximately 20 μm), as second cladding 530 is typically not meant to guide light. Although second cladding 530 is typically non-light-guiding, various embodiments of the invention incorporate the second cladding 530 because it provides a boundary to confine guiding modes (i.e., laser power) in the inner layers. Since there are tails of guiding modes crossing over the boundary (known as evanescent waves) and penetrating into the non-guiding second cladding up to a few microns, the thickness of the second cladding layer is preferably at least 10 μm.

The fiber 500 of FIG. 5 may be utilized in conjunction with, for example, a hybrid laser system having a good beam quality longer-wavelength (e.g., NIR) laser and a bad (or worse) beam quality shorter-wavelength (e.g., blue or UV) laser. The depicted fiber 500 does not have a “discrete” ring core as in the example fiber 200 of FIG. 2. In various embodiments, the fiber 500 of FIG. 5 is intended to have the longer-wavelength (e.g., NIR) laser mainly confined in the center core 510 and the shorter-wavelength (e.g., blue or UV) laser filling both the center core 510 and the first cladding 520.

The present inventors have demonstrated improvements in some welding applications in terms of speed and quality with a hybrid laser having a shorter-wavelength (e.g., blue or UV) laser spot larger than the longer-wavelength (e.g., NIR) laser spot when compared to some other laser combinations. In other words, the design of the fiber 500 of FIG. 5 is not simply a compromise to operate with lasers that are currently commercially available, but also to meet certain application demands.

In the exemplary fiber 500 of FIG. 5, since the shorter-wavelength (e.g., blue or UV) laser will spread over the low-OH center core 510 without NA restriction, the overall absorption at shorter wavelengths of this fiber will be somewhat higher than in a fiber 200 in accordance with FIGS. 2 and 3. For example, assuming that a blue laser fills both regions (510 and 520) uniformly and the diameters of the center core 510 and the first clad 520 are approximately 100 μm and approximately 400 μm, respectively, then the average absorption at blue will be 1/16×1.5%+ 15/16×0.7%=0.75%, an increase of ˜7% over a case in which the blue laser is fully in a high-OH region.

With the fiber 500 of FIG. 5, two lasers may be aligned in parallel or near parallel with a tight longer-wavelength (e.g., NIR) focal spot at center and a considerably larger shorter-wavelength (e.g., blue or UV) focal spot at or near center. Advantageously, since there is no need to completely locate one focal spot on one side of the fiber, the overall fiber diameter of this design may be considerably smaller than those of FIGS. 2 and 3, at least when in-coupling lasers of similar beam quality.

In an alternate embodiment to that of fiber 500 of FIG. 5, the low-OH and high-OH fused silica regions are switched, so that the shorter-wavelength (e.g., blue or UV) light would be in the center core 510 and the longer-wavelength (e.g., NIR) light would be in both the center core 510 and the first cladding 520 with a similar restriction of n1 as described above.

In various embodiments of the invention, the output end of the optical fiber (i.e., the end of the fiber opposite the input end receiving the beam) may have coupled thereto a laser head for directing the output beam toward a workpiece to be processed. The laser head may include, consist essentially of, or consist of one or more optical elements for focusing and/or collimating the output beam, and/or controlling the polarization and/or the trajectory of the beam. For example, laser heads in accordance with embodiments of the invention may include one or more collimators (i.e., collimating lenses) and/or focusing optics (e.g., one or more focusing lenses). A laser head may not include a collimator if the beam(s) entering the laser head are already collimated. Laser heads in accordance with various embodiments may also include one or more protective window, a focus-adjustment mechanism (manual or automatic, e.g., one or more dials and/or switches and/or selection buttons). Laser heads may also include one or more monitoring systems for, e.g., laser power, target material temperature and/or reflectivity, plasma spectrum, etc. A laser head may also include optical elements for beam shaping and/or adjustment of beam quality (e.g., variable BPP) and may also include control systems for polarization of the beam and/or the trajectory of the focusing spot.

The laser head may be positioned to emit the output beam toward a workpiece and/or toward a platform or positionable gantry on which the workpiece may be disposed. In various embodiments, the laser head includes one or more optical elements for rotating the output beam. Such embodiments may be particularly useful when the output beam is not rotationally symmetric. Various embodiments of the invention may include laser heads configured to deliver asymmetric and/or rotatable output beams as described in U.S. patent application Ser. No. 17/123,305, filed on Dec. 16, 2020, the entire disclosure of which is incorporated by reference herein. In this manner, output beams that are not rotationally symmetric may be aligned and rotated as desired along processing paths that have directional changes.

In various embodiments, a computer-based controller may initiate and control processes performed using the output beam (and/or the laser head). For example, the controller may even control the motion of the fiber and/or the laser head relative to the workpiece via control of, e.g., one or more actuators. The controller may also operate a conventional positioning system configured to cause relative movement between the output laser beam and the workpiece being processed. For example, the positioning system may be any controllable optical, mechanical or opto-mechanical system for directing the beam through a processing path along a two- or three-dimensional workpiece. During processing, the controller may operate the positioning system and the laser system so that the laser beam traverses a processing path along the workpiece. The processing path may be provided by a user and stored in an onboard or remote memory, which may also store parameters relating to the type of processing (cutting, welding, etc.) and the beam parameters (e.g., wavelength, beam shape, intensity, and/or BPP) necessary or desired to carry out that processing. In this regard, a local or remote database may maintain a library of materials and thicknesses that the system will process. The stored values may include beam properties suitable for various processes of the material (e.g., piercing, cutting, etc.), the type of processing, and/or the geometry of the processing path. Moreover, in embodiments featuring multiple input beams, the controller may control the relative power level of each beam, the operation of the beams (e.g., in sequence and/or simultaneously), etc., and such control may be based on one or more properties of the workpiece, sensed parameters or feedback from the workpiece, and/or stored values related to various processes and/or the geometry of the processing path.

As is well understood in the plotting and scanning art, the requisite relative motion between the output beam (and/or the laser head) and the workpiece may be produced by optical deflection of the beam using a movable mirror, physical movement of the laser using a gantry, lead-screw or other arrangement, and/or a mechanical arrangement for moving the workpiece rather than (or in addition to) the beam. The controller may, in some embodiments, receive feedback regarding the position and/or processing efficacy of the beam relative to the workpiece from a feedback unit, which will be connected to suitable monitoring sensors.

Embodiments of the invention may enable a user to process (e.g., cut, drill, or weld) a workpiece along a desired processing path, and the properties of the output beam (e.g., wavelength(s), beam shape, BPP, or both), power level of the output beam, and/or maximum processing speed are selected based on factors such as, but not limited to, the composition of the workpiece, the thickness of the workpiece, the geometry of the processing path, etc. For example, a user may select or preprogram the desired processing path and/or type (and/or other properties such as thickness) of the workpiece into the system using any suitable input device or by means of file transfer. Thereafter, the controller may determine optimum processing speeds or output beam power levels as a function of location along the processing path. In operation, the controller may operate the laser system and positioning of the workpiece to process the workpiece along the preprogrammed path, utilizing the proper output beam properties for processes such as cutting or welding. If the composition and/or thickness of the material being processed changes, the location and nature of the change may be programmed, and the controller may adjust the laser beam properties and/or the rate of relative motion between the workpiece and the beam accordingly.

In addition, the laser system may incorporate one or more systems for detecting the thickness of the workpiece and/or heights of features thereon. For example, the laser system may incorporate systems (or components thereof) for interferometric depth measurement of the workpiece, as detailed in U.S. patent application Ser. No. 14/676,070, filed on Apr. 1, 2015, the entire disclosure of which is incorporated by reference herein. Such depth or thickness information may be utilized by the controller to control the output beam properties and/or processing speed to optimize the processing of the workpiece, e.g., in accordance with records in the database corresponding to the type of material being processed.

The controller may be provided as either software, hardware, or some combination thereof. For example, the system may be implemented on one or more conventional server-class computers, such as a PC having a CPU board containing one or more processors such as the Pentium or Celeron family of processors manufactured by Intel Corporation of Santa Clara, Calif., the 680x0 and POWER PC family of processors manufactured by Motorola Corporation of Schaumburg, Ill., and/or the ATHLON line of processors manufactured by Advanced Micro Devices, Inc., of Sunnyvale, Calif. The processor may also include a main memory unit for storing programs and/or data relating to the methods described herein. The memory may include random access memory (RAM), read only memory (ROM), and/or FLASH memory residing on commonly available hardware such as one or more application specific integrated circuits (ASIC), field programmable gate arrays (FPGA), electrically erasable programmable read-only memories (EEPROM), programmable read-only memories (PROM), programmable logic devices (PLD), or read-only memory devices (ROM). In some embodiments, the programs may be provided using external RAM and/or ROM such as optical disks, magnetic disks, as well as other commonly used storage devices. For embodiments in which the functions are provided as one or more software programs, the programs may be written in any of a number of high level languages such as FORTRAN, PASCAL, JAVA, C, C++, C #, BASIC, various scripting languages, and/or HTML. Additionally, the software may be implemented in an assembly language directed to the microprocessor resident on a target computer; for example, the software may be implemented in Intel 80×86 assembly language if it is configured to run on an IBM PC or PC clone. The software may be embodied on an article of manufacture including, but not limited to, a floppy disk, a jump drive, a hard disk, an optical disk, a magnetic tape, a PROM, an EPROM, EEPROM, field-programmable gate array, or CD-ROM.

Laser systems and laser delivery systems in accordance with embodiments of the present invention and detailed herein may be utilized in and/or with WBC laser systems. Specifically, in various embodiments of the invention, multi-wavelength output beams of WBC laser systems may be utilized as the input beams for optical fibers and laser beam delivery systems as detailed herein. For example, output beams from WBC laser systems or resonator may be utilized as the longer-wavelength (e.g., NIR) beam, shorter-wavelength (e.g., blue or UV) beam, or both, in accordance with embodiments of the invention. In various embodiments, WBC laser systems may be utilized to generate multi-wavelength input beams having a range of wavelengths in the longer-wavelength (e.g., NIR) range, shorter-wavelength (e.g., blue or UV) range, or both, in accordance with embodiments of the invention.

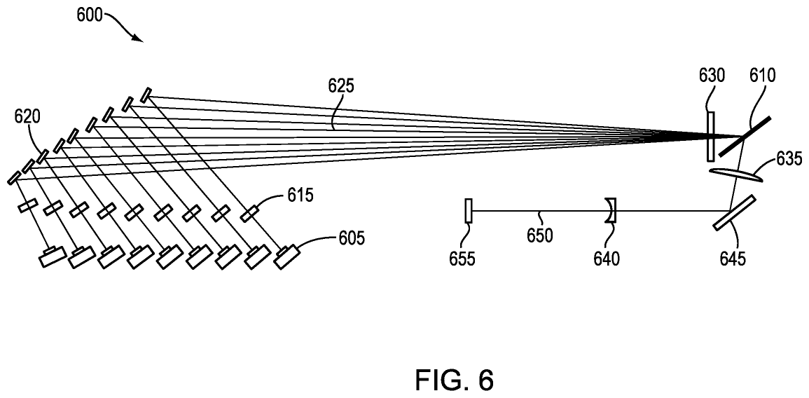

FIG. 6 schematically depicts various components of a WBC laser system (or “resonator”) 600 that may be utilized to form input beams used in embodiments of the present invention. In the depicted embodiment, resonator 600 combines the beams emitted by nine different diode bars (as utilized herein, “diode bar” refers to any multi-beam emitter, i.e., an emitter from which multiple beams are emitted from a single package). Embodiments of the invention may be utilized with fewer or more than nine emitters. In accordance with embodiments of the invention, each emitter may emit a single beam, or, each of the emitters may emit multiple beams. The view of FIG. 6 is along the WBC dimension, i.e., the dimension in which the beams from the bars are combined. The exemplary resonator 600 features nine diode bars 605, and each diode bar 605 includes, consists essentially of, or consists of an array (e.g., one-dimensional array) of emitters along the WBC dimension. In various embodiments, each emitter of a diode bar 605 emits a non-symmetrical beam having a larger divergence in one direction (known as the “fast axis,” here oriented vertically relative to the WBC dimension) and a smaller divergence in the perpendicular direction (known as the “slow axis,” here along the WBC dimension).

In various embodiments, each of the diode bars 605 is associated with (e.g., attached or otherwise optically coupled to) a fast-axis collimator (FAC)/optical twister microlens assembly that collimates the fast axis of the emitted beams while rotating the fast and slow axes of the beams by 90°, such that the slow axis of each emitted beam is perpendicular to the WBC dimension downstream of the microlens assembly. The microlens assembly also converges the chief rays of the emitters from each diode bar 605 toward a dispersive element 610. Suitable microlens assemblies are described in U.S. Pat. No. 8,553,327, filed on Mar. 7, 2011, and U.S. Pat. No. 9,746,679, filed on Jun. 8, 2015, the entire disclosure of each of which is hereby incorporated by reference herein.

In embodiments of the invention in which both a FAC lens and an optical twister (e.g., as a microlens assembly) are associated with each of the beam emitters and/or emitted beams, and SAC lenses (as detailed below) affect the beams in the non-WBC dimension. In other embodiments, the emitted beams are not rotated, and FAC lenses may be utilized to alter pointing angles in the non-WBC dimension. Thus, it is understood that references to SAC lenses herein generally refer to lenses having power in the non-WBC dimension, and such lenses may include FAC lenses in various embodiments. Thus, in various embodiments, for example embodiments in which emitted beams are not rotated and/or the fast axes of the beams are in the non-WBC dimension, FAC lenses may be utilized as detailed herein for SAC lenses.

As shown in FIG. 6, resonator 600 also features a set of SAC lenses 615, one SAC lens 615 associated with, and receiving beams from, one of the diode bars 605. Each of the SAC lenses 615 collimates the slow axes of the beams emitted from a single diode bar 605. After collimation in the slow axis by the SAC lenses 615, the beams propagate to a set of interleaving mirrors 620, which redirect the beams 625 toward the dispersive element 610. The arrangement of the interleaving mirrors 620 enables the free space between the diode bars 605 to be reduced or minimized. Upstream of the dispersive element 610 (which may include, consist essentially of, or consist of, for example, a diffraction grating such as the transmissive diffraction grating depicted in FIG. 6, or a reflective diffraction grating), a lens 630 may optionally be utilized to collimate the sub-beams (i.e., emitted rays other than the chief rays) from the diode bars 605. In various embodiments, the lens 630 is disposed at an optical distance away from the diode bars 605 that is substantially equal to the focal length of the lens 630. Note that, in typical embodiments, the overlap of the chief rays at the dispersive element 610 is primarily due to the redirection of the interleaving mirrors 620, rather than the focusing power of the lens 630.

Also depicted in FIG. 6 are lenses 635, 640, which form an optical telescope for mitigation of optical cross-talk, as disclosed in U.S. Pat. No. 9,256,073, filed on Mar. 15, 2013, and U.S. Pat. No. 9,268,142, filed on Jun. 23, 2015, the entire disclosure of which is hereby incorporated by reference herein. Resonator 600 may also include one or more optional folding mirrors 645 for redirection of the beams such that the resonator 600 may fit within a smaller physical footprint. The dispersive element 610 combines the beams from the diode bars 605 into a single, multi-wavelength beam 650, which propagates to a partially reflective output coupler 655. The coupler 655 transmits a portion of the beam as the output beam of resonator 600 while reflecting another portion of the beam back to the dispersive element 610 and thence to the diode bars 605 as feedback to stabilize the emission wavelengths of each of the beams.

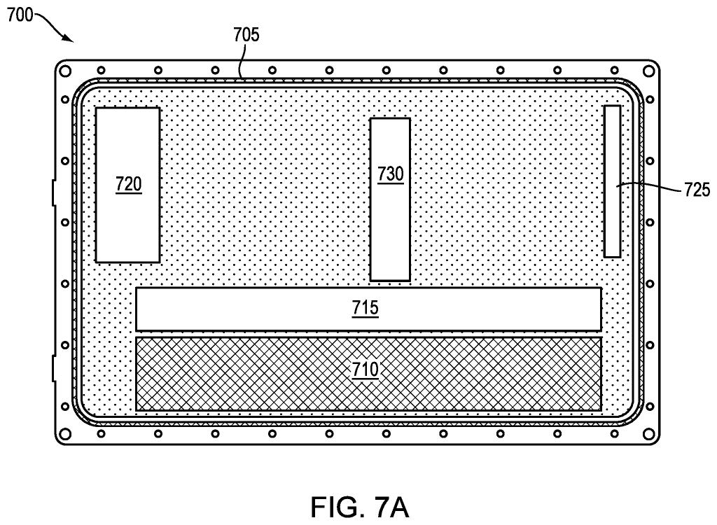

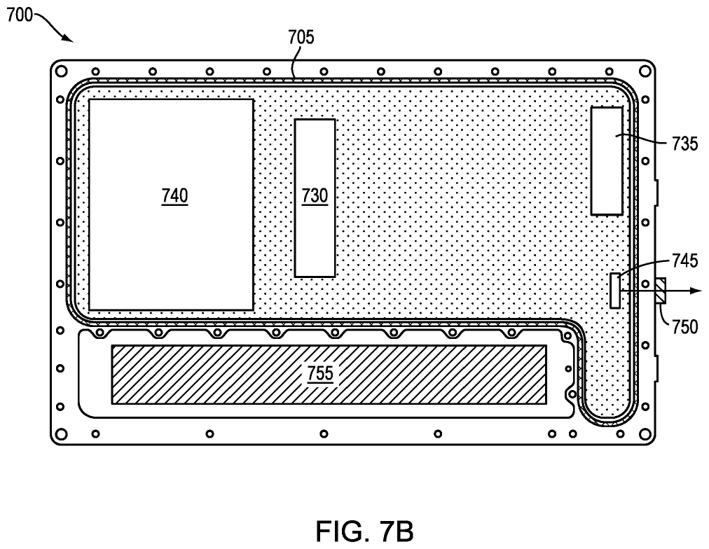

Various embodiments of the invention implement an external cavity laser system and reduce the required size of the resonator using a laser cavity that extends along opposing sides of the resonator. FIGS. 7A and 7B depict opposing sides of a resonator 700 that collectively constitute a single laser cavity (connected by a central opening, as detailed below). In accordance with embodiments of the invention, both sides of resonator 700 may be sealed, e.g., along a sealing path 705. For example, a solid cover plate may be sealed over each side of the resonator 700 along the sealing paths 705 to seal the laser cavity within the resonator 700. In various embodiments, each cover plate may be fastened and/or sealed to resonator 700 via fasteners (e.g., screws, bolts, rivets, etc.) that extend into (and may mechanically engage with, e.g., threadingly engage with) apertures defined in resonator 700. In other embodiments, each cover plate may be sealed along its sealing path 705 via a technique such as welding, brazing, or use of an adhesive material.

In various embodiments, reflectors such as mirrors may be utilized to direct the beams from one or more beam emitters within the laser cavity, and, since the laser cavity extends along both sides, the overall size of the resonator 700 may be correspondingly reduced for the same cavity size (e.g., compared to a resonator having an optical cavity on only one side).

In the exemplary embodiment shown in FIGS. 7A and 7B, beams from beam emitters (e.g., beam emitters 605 shown in FIG. 6) disposed in mounting area 710 may be focused by a group of lenses (and/or other optical elements; for example, SAC lenses 615 shown in FIG. 6) disposed in lens area 715 toward a group of mirrors (e.g., interleaving mirrors 620 shown in FIG. 6) in a mirror area 720. From mirror area 720, the beams from the beam emitters may be directed to another mirror area 725 (containing multiple reflectors such as mirrors) and thence through an opening 730 to the remaining portion of the laser cavity on the other side of resonator 700. As shown in FIG. 7B, the beams may be directed to a mirror area 735 (containing multiple reflectors such as mirrors), which reflects the beams to a beam-combining area 740. In example embodiments, the beam-combining area 740 may include therewithin the diffusive element 610 (and, in some embodiments, the output coupler 645) shown in FIG. 6. In various embodiments, the beams each have a different wavelength, and the beams are combined in beam-combining area 740 into an output beam composed of the multiple wavelengths. The beam from the beam-combining area 740 may be directed to a mirror 745 (which, in various embodiments, may be partially reflective output coupler 645) and thence to an output 750 for emission from the resonator 700. For example, the output may be a window for emission of the beam therethrough or an optical coupler configured to connect directly to an optical fiber such as an optical fiber in accordance with embodiments of the invention. In various embodiments, the output may transmit the beam to a fiber-optic module (see below) for coupling into an optical fiber. In other embodiments, the output beam may be transmitted to a beam-combining module (see below), and combined with output beams emitted by other resonators. The resulting combined beam may be transmitted to a fiber-optic module for coupling into an optical fiber, and/or utilized for processing of a workpiece.

As shown in FIG. 7B, resonator 700 may also include a liquid coolant cavity 755. The liquid coolant cavity 755 is, in various embodiments, a hollow cavity configured to contain liquid coolant (e.g., water, glycol, or other heat-transfer fluid) directly beneath the mounting area 710. The liquid coolant may flow into and out of the cavity 755 via a fluid inlet and a fluid outlet (not shown), which may be fluidly coupled to, e.g., a reservoir of coolant and/or a heat exchanger for cooling fluid heated by the beam emitters. Embodiments of the invention may feature a control system that controls the rate of fluid flow into and out of the cavity 755 based on one or more sensed characteristics, e.g., temperature of the beam emitters, the cooling fluid, and/or one or more other components of and/or positions within resonator 700. In various embodiments, the laser cavity of resonator 700 may be sealed without sealing or covering of the optical coolant cavity 755, thereby leaving the optical coolant cavity 755 accessible (e.g., for service, maintenance, or cleaning) without the need to unseal or expose the more delicate components disposed within the laser cavity.

As mentioned above, in various embodiments of the invention, multiple beams having different wavelengths may be coupled into the optical fiber to facilitate the processing of various workpieces. For example, embodiments of the invention utilize a secondary, shorter-wavelength laser for initiation of a cutting operation (e.g., piercing) when a material is in the solid state, and, once the material is molten, a primary, longer-wavelength laser is utilized for processes such as cutting of the material. For example, at least in the solid state, the absorption of most metals increases as the laser wavelength decreases. Notably, aluminum has an absorption peak at approximately 810 nm, and metals such as copper, gold, and silver are very reflective and exhibit very low absorption at near-infrared wavelengths and beyond (e.g., at wavelengths of approximately 800 nm or 1000 nm and higher). Thus for many materials (e.g., metallic materials), below the melting point of the material, the absorption is significantly higher for the shorter-wavelength light. However, when the melting point is reached and the surface begins to melt, the absorption increases significantly and becomes substantially independent of wavelength. The absorption continues to increase as the temperature increases to the vaporization temperature (e.g., the regime where cutting is performed), whereupon the absorption tends to level off at a significant level. Thus, embodiments of the invention utilize the secondary, shorter-wavelength beam for initiation of a cutting operation (e.g., piercing) when the material is in the solid state, and, once the material is molten, the primary, longer-wavelength beam is utilized for processes such as cutting of the material. In other examples, other materials, e.g., plastic, glass, or polymeric materials, may exhibit the opposite behavior, and thus for such materials, embodiments of the invention may utilize the primary, longer-wavelength laser for initiation of a cutting operation (e.g., piercing) when the material is in the solid state, and, once the material is molten, the secondary, shorter-wavelength laser is utilized for processes such as cutting of the material.

In various embodiments, the primary and secondary lasers are different types of lasers. For example, the primary laser may include, consist essentially of, or consist of a direct-diode laser (e.g., emitting in free space or coupled into an optical fiber), a fiber laser, or a solid-state laser (i.e., a laser utilizing a solid gain medium such as a glass or crystal doped with one or more rare-earth elements). In various embodiments, the secondary laser may include, consist essentially of, or consist of a direct-diode laser (e.g., emitting in free space or coupled into an optical fiber), a gas laser, or a solid-state laser. In various embodiments, direct-diode WBC lasers may be preferred for the primary laser and/or the secondary laser due to their capability to process materials (e.g., metallic materials) with higher quality. Without wishing to be bound by theory, WBC lasers may provide better quality due to their broadband nature resulting from the combination of tens (or even hundreds) of discrete emitters each having a different wavelength—this may scramble laser coherence and speckle while smoothing the laser intensity profile in both the spatial domain and the time domain.

Thus, as detailed herein, either or both of the primary laser and secondary laser may emit multi-wavelength beams. In accordance with embodiments of the invention, the “wavelength” or “primary wavelength” of such a multi-wavelength beam may correspond to the central (i.e., middle) and/or most intense wavelength emitted by the laser. As known to those of skill in the art, virtually all laser outputs include a band of multiple wavelengths, although laser wavelength bands tend to be quite narrow. For example, a fiber laser emitting at 1064 nm may have a very narrow band of about 2 nm, while a WBC direct-diode laser emitting at 970 nm may have a band of about 40 nm.

In various embodiments, the primary laser beam has a wavelength (or range of wavelengths) ranging from approximately 780 nm to approximately 2.5 μm, from approximately 780 nm to approximately 1064 nm, from approximately 780 nm to approximately 1000 nm, approximately 870 nm to approximately 2.5 μm, from approximately 870 nm to approximately 1064 nm, or from approximately 870 nm to approximately 1000 nm. In particular embodiments, the wavelength (or primary or center wavelength) of the primary laser beam may be, for example, approximately 1064 nm, approximately 970 nm, approximately 780 or 850 to approximately 1060 nm, or approximately 950 nm to approximately 1070 nm.

In various embodiments, the secondary laser beam has a wavelength (or range of wavelengths) ranging from approximately 300 nm to approximately 740 nm, approximately 400 nm to approximately 740 nm, approximately 530 nm to approximately 740 nm, approximately 300 nm to approximately 810 nm, approximately 400 nm to approximately 810 nm, or approximately 530 nm to approximately 810 nm. In various embodiments, the wavelength of the secondary laser beam is in the UV or visible range, although the wavelength may extend up to approximately 810 nm for materials (e.g., aluminum) having absorption peaks in that range. In particular embodiments, the wavelength (or primary or center wavelength) of the secondary laser beam may be, for example, approximately 810 nm, approximately 400—approximately 460 nm, or approximately 532 nm. In various embodiments, the primary laser source and/or the secondary laser source is a WBC laser emitting a broadband, multi-wavelength laser beam. In various embodiments, such lasers may have bandwidths ranging from, for example, approximately 10 nm to approximately 60 nm.

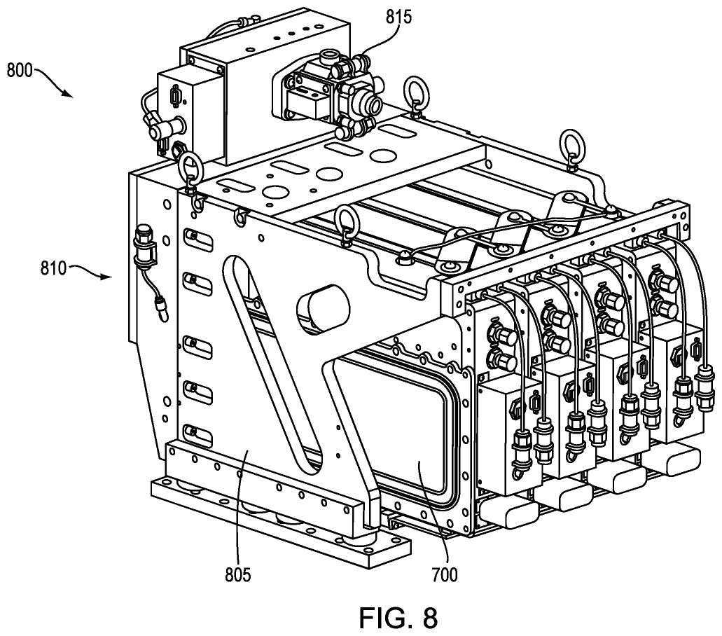

Thus, in various embodiments, a laser system incorporates multiple resonators 700, and the output beams from the resonators 700 are combined downstream (e.g., within a master housing and/or by one or more optical elements) into a single output beam that may be coupled into an optical fiber and then directed to a workpiece for processing (e.g., welding, cutting, annealing, etc.). For example, FIG. 8 depicts an exemplary laser system (or “laser engine”) 800 in accordance with embodiments of the invention. In laser system 800, multiple laser resonators 700 are mounted within a master housing 805, and the output beams from the resonators 700 are emitted into a beam-combining module 810 and thence to a fiber optic module 815. In exemplary embodiments, beam-combining module 810 may contain one or more optical elements, such as mirrors, dichroic mirrors, lenses, prisms, dispersive elements, polarization beam combiners, etc., that may combine beams received from the various resonators into one or more output beams. In various embodiments, the fiber-optic module 815 may contain, for example, one or more optical elements for adjusting output laser beams, as well as interface hardware connecting to the optical fiber for coupling of the beams therein. For example, the fiber-optic module 815 may include some or all of the components depicted in FIG. 4 utilized to couple beam energy into the optical fiber. While laser engine 800 is depicted as including four resonators 700, laser engines in accordance with embodiments of the invention may include one, two, three, or five or more laser resonators. Each resonator may emit a beam having a different wavelength (or a different range of wavelengths), and these beams may be combined and coupled in the fiber as detailed herein.

The various wavelengths or wavelength ranges for the primary and secondary beams may be utilized for the processing of various types of workpieces, and in particular workpieces including, consisting essentially of, or consisting of one or more metallic materials. In other embodiments, the wavelengths or wavelength ranges of the “primary” and “secondary” beams may be switched for other types of workpieces, as detailed herein, for example for the processing of workpieces including, consisting essentially of, or consisting of glass, plastic, paper, or one or more polymeric or other non-metallic materials. Various different wavelength combinations may be utilized, as described in U.S. patent application Ser. No. 16/984,489, filed on Aug. 4, 2020, and U.S. patent application Ser. No. 17/363,172, filed on Jun. 30, 2021, the entire disclosure of each of which is incorporated by reference herein.

In various embodiments, one or more (or even all) of the primary beam (and/or the primary beam source), the secondary beam (and/or the secondary beam source), the optical fiber, and/or optical elements utilized to direct the beams and in-couple them into the fiber, are responsive to a computer-based controller. For example, the controller may initiate processes performed using the optical fiber (and, in various embodiments, a laser head coupled to the output end thereof) and switch on/off (and/or modulate the output power level of) the primary beam and secondary laser beam accordingly. In various embodiments, the controller may even control the motion of the laser head and/or optical fiber relative to the workpiece via control of, e.g., one or more actuators. The controller may also operate a conventional positioning system configured to cause relative movement between the output laser beam and the workpiece being processed.

As is well understood in the plotting and scanning art, the requisite relative motion between the output beam and the workpiece may be produced by optical deflection of the beam using a movable mirror, physical movement of the laser using a gantry, lead-screw or other arrangement, and/or a mechanical arrangement for moving the workpiece rather than (or in addition to) the beam. The controller may, in some embodiments, receive feedback regarding the position and/or processing efficacy of the beam relative to the workpiece from a feedback unit, which will be connected to suitable monitoring sensors.

In various embodiments, the controller controls the on/off switching and/or the output power level of the primary beam and secondary beam based on sensed information related to the workpiece (e.g., its surface). For example, the laser system may incorporate one or more optical and/or temperature sensors that detect when at least a portion of the surface of the workpiece is molten (via, e.g., a reflectivity change and/or the temperature reaching the melting point of the material; such sensors are conventional and may be provided without undue experimentation). In various embodiments, the secondary beam is utilized to heat the workpiece surface until at least a portion of the surface of the workpiece is molten, or even to pierce through at least a portion of the thickness of the workpiece, and then the primary beam is utilized to cut the workpiece along a processing path originating from the at least partially molten area. In other embodiments, the controller merely switches from the secondary beam to the primary beam after a timed delay, the duration of which may be estimated based on factors such as the type of material, the thickness of the material, the spot size of the output beam, etc.

In various embodiments, both the primary laser beam and the secondary beam are utilized for both piercing and cutting, and therefore both coupled into the optical fiber simultaneously during both operations, but the power of the primary beam is increased for cutting (and, thus, relatively decreased for piercing) and the power of the secondary beam is increased for piercing (and, thus, relatively decreased for cutting). Such dual-beam embodiments may provide the advantage of higher quality cuts and piercings, due to the broader spectral band of the combined output beam, which significantly decreases laser coherence and speckle. In some embodiments, the primary beam is not utilized until at least a portion of the workpiece surface is rendered molten by the secondary beam, and then both beams are utilized for the subsequent cut. Such embodiments will prevent or significantly reduce deleterious back reflections from the workpiece surface that might damage components (e.g., optical elements) of the laser system.

Embodiments of the invention may enable a user to process (e.g., cut or weld) a workpiece along a desired processing path, and the composition of the output beam (e.g., whether including the primary beam, the secondary beam, or both), power level of the output beam (and/or of the primary beam and/or the secondary beam), and maximum processing speed is selected based on factors such as, but not limited to, the composition of the workpiece, the thickness of the workpiece, the geometry of the processing path, etc. For example, a user may select or preprogram the desired processing path and/or type (and/or other properties such as thickness) of the workpiece into the system using any suitable input device or by means of file transfer. Thereafter, the controller may determine optimum output beam composition (e.g., switching between the primary and secondary beams, and/or their relative power levels) as a function of location along the processing path. In operation, the controller may operate the laser system and positioning of the workpiece to process the workpiece along the preprogrammed path, utilizing the proper output beam compositions for processes such as piercing and cutting. If the composition and/or thickness of the material being processed changes, the location and nature of the change may be programmed, and the controller may adjust the laser beam composition and/or the rate of relative motion between the workpiece and the beam accordingly.

In addition, the laser system may incorporate one or more systems for detecting the thickness of the workpiece and/or heights of features thereon. For example, the laser system may incorporate systems (or components thereof) for interferometric depth measurement of the workpiece, as detailed in U.S. patent application Ser. No. 14/676,070, filed on Apr. 1, 2015, the entire disclosure of which is incorporated by reference herein. Such depth or thickness information may be utilized by the controller to control the output beam composition to optimize the processing (e.g., cutting or piercing) of the workpiece, e.g., in accordance with records in the database corresponding to the type of material being processed.

The terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed.

1. A laser system for processing a workpiece, the laser system comprising:
an optical fiber having an input end and an output end opposite the input end, wherein the optical fiber comprises (i) a center core having a refractive index n0, (ii) surrounding the center core, a first cladding layer having a refractive index n1, (iii) surrounding the first cladding layer, a ring core having a refractive index n2, and (iv) surrounding the ring core, a second cladding layer having a refractive index n3, wherein n3 is less than n0 and n3 is less than n2;
a primary laser emitter configured to emit a primary laser beam;
a secondary laser emitter configured to emit a secondary laser beam, wherein a wavelength of the primary laser beam is longer than a wavelength of the secondary laser beam; and
a coupling mechanism for coupling the primary laser beam and the secondary laser beam into the input end of the optical fiber,
wherein (i) the center core is composed of doped or undoped low-OH fused silica having an OH content of 10 ppm or less, and the ring core is composed of doped or undoped high-OH fused silica having an OH content of 200 ppm or more, or (ii) the center core is composed of doped or undoped high-OH fused silica having an OH content of 200 ppm or more, and the ring core is composed of doped or undoped low-OH fused silica having an OH content of 10 ppm or less.

2. The laser system of claim 1, wherein the coupling mechanism comprises one or more of a focusing lens, a prism, and a dichroic mirror.

3. The laser system of claim 1, wherein the primary laser beam comprises infrared and/or near-infrared light, and the secondary laser beam comprises visible and/or ultraviolet light.

4. The laser system of claim 1, wherein:
the center core is composed of doped or undoped high-OH fused silica;
the ring core is composed of doped or undoped low-OH fused silica;
the coupling mechanism is configured to couple the primary laser beam into the ring core; and
the coupling mechanism is configured to couple the secondary laser beam into the center core.

5. The laser system of claim 4, wherein:
n0 is approximately equal to n2; and
n1 is approximately equal to n3.

6. The laser system of claim 5, wherein a thickness of the first cladding layer is less than approximately 15 μm, less than approximately 10 μm, or less than approximately 5 μm.

7. The laser system of claim 4, wherein:
n0 is approximately equal to n2;
n1 is greater than n3;
sqrt(n1²−n3²)>0.15;
sqrt(n0²−n1²)>0.1; and
the first cladding layer is composed of doped or undoped low-OH fused silica.

8. The laser system of claim 7, wherein the coupling mechanism is configured to also couple the primary laser beam into the first cladding layer.

9. The laser system of claim 8, wherein the coupling mechanism is configured to also couple the secondary laser beam into the first cladding layer.

10. The laser system of claim 7, wherein the coupling mechanism is configured to also couple the secondary laser beam into the first cladding layer.

11. The laser system of claim 4, wherein:
n0 is less than n2;
n1 is greater than n3;
sqrt(n1²−n3²)>0.15;
sqrt(n0²−n1²)>0.1;
sqrt(n2²−n1²)>0.13; and
the first cladding layer is composed of doped or undoped high-OH fused silica.

12. The laser system of claim 11, wherein the coupling mechanism is configured to also couple the secondary laser beam into the first cladding layer.

13. The laser system of claim 1, wherein:
the center core is composed of doped or undoped low-OH fused silica;
the ring core is composed of doped or undoped high-OH fused silica;
the coupling mechanism is configured to couple the primary laser beam into the ring core; and
the coupling mechanism is configured to couple the secondary laser beam into the center core.

14. The laser system of claim 13, wherein:
n0 is approximately equal to n2; and
n1 is approximately equal to n3.

15. The laser system of claim 14, wherein a thickness of the first cladding layer is less than approximately 15 μm, less than approximately 10 μm, or less than approximately 5 μm.

16. The laser system of claim 1, wherein the output end of the optical fiber is coupled to a laser head containing one or more optical elements therein.

17. The laser system of claim 1, wherein the primary laser emitter comprises:
one or more beam sources emitting a plurality of discrete beams;
focusing optics for focusing the plurality of beams toward a dispersive element;
the dispersive element for receiving and dispersing the received focused beams; and
a partially reflective output coupler positioned to receive the dispersed beams, transmit a portion of the dispersed beams therethrough as the primary laser beam, and reflect a second portion of the dispersed beams back toward the dispersive element,
wherein the primary laser beam is composed of multiple wavelengths.

18. The laser system of claim 17, wherein the dispersive element comprises a diffraction grating.

19. The laser system of claim 1, wherein the secondary laser emitter comprises:
one or more beam sources emitting a plurality of discrete beams;
focusing optics for focusing the plurality of beams toward a dispersive element;
the dispersive element for receiving and dispersing the received focused beams; and
a partially reflective output coupler positioned to receive the dispersed beams, transmit a portion of the dispersed beams therethrough as the secondary laser beam, and reflect a second portion of the dispersed beams back toward the dispersive element,
wherein the secondary laser beam is composed of multiple wavelengths.

20. The laser system of claim 19, wherein the dispersive element comprises a diffraction grating.

21.-56. (canceled)
